(19) United States
(12) Patent Application Publication
(10) Pub. No.: US 2009/0050200 A1
(43) Pub. Date: Feb. 26, 2009

(54) SOLAR CELL

(75) Inventor: GA-LANE CHEN, Santa Clara, CA (US)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Taipei Hsien (TW)

(21) Appl. No.: 12/039,029

(22) Filed: Feb. 28, 2008

(30) Foreign Application Priority Data
Aug. 20, 2007 (CN) 200710201402.8

(51) Int. Cl. H01L 31/028; H01L 31/04

(52) U.S. Cl. 136/256; 136/252; 136/258; 977/742

(57) ABSTRACT

A solar cell includes a back metal-contact layer, a P-type semiconductor layer, a P-N junction layer, an N-type semiconductor layer, and a transparent electrically conductive layer. The P-type semiconductor layer is formed on the back metal-contact layer. The P-N junction layer is formed on the P-type semiconductor layer. The N-type semiconductor layer is formed on the P-N junction layer. The transparent electrically conductive layer is formed on the N-type semiconductor layer. The transparent electrically conductive layer functions as a front contact layer, and has a basic film and a plurality of photocatalyst nano-particles dispersed in the basic film.

### BACKGROUND

1. Technical Field

The present invention relates to solar cells, and particularly, to a solar cell with photocatalyst nano-particles.

2. Description of Related Art

Currently, various solar cells have been designed to receive and convert sunlight into electrical energy. Such solar cells have been applied on roofs of buildings and cars, or applied on portable electronic device.

A typical solar cell includes at least a P-type semiconductor layer and an N-type semiconductor layer. When sunlight projects on surfaces of the P-type semiconductor layer or the N-type semiconductor layer, a part of the sunlight is unavoidably reflected by the surfaces, and the other is absorbed. Photons in the absorbed sunlight collide with electrons in the P-type semiconductor layer or the N-type semiconductor layer, thereby, electron-hole pairs are generated, and thus an electric field is formed between the P-type semiconductor layer and the N-type semiconductor layer. The electric field can power a load connected to the P-type semiconductor layer and the N-type semiconductor layer.

A photon-electron conversion efficiency of the solar cell is limited by the surface area exposed to the sunlight. However, as the solar cell is exposed to outside, the surface of the solar cell is prone to becoming dirty, in this way, the photon-electron conversion efficiency thereof may be lowered.

What is needed, therefore, is a solar cell with self cleaning function.

### SUMMARY

In a present embodiment, an exemplary solar cell includes a back metal-contact layer, a P-type semiconductor layer, a P-N junction layer, an N-type semiconductor layer, and a transparent electrically conductive layer. The P-type semiconductor layer is formed on the back metal-contact layer. The P-N junction layer is formed on the P-type semiconductor layer. The N-type semiconductor layer is formed on the P-N junction layer. The transparent electrically conductive layer is formed on the N-type semiconductor layer. The transparent electrically conductive layer functions as a front contact layer, and has a basic film and a plurality of photocatalyst nano-particles dispersed in the basic film.

Other advantages and novel features of the present invention will become more apparent from the following detailed description of preferred embodiment when taken in conjunction with the accompanying drawings.

### BRIEF DESCRIPTION OF THE DRAWINGS

Many aspects of the solar cell can be better understood with reference to the following drawing. The components in the drawing are not necessarily drawn to scale, the emphasis instead being placed upon clearly illustrating the principles of the present solar cell. Moreover, in the drawing, like reference numerals designate corresponding parts throughout the several views.

FIG. 1 is a schematic view of a solar cell according to an embodiment of the present invention.

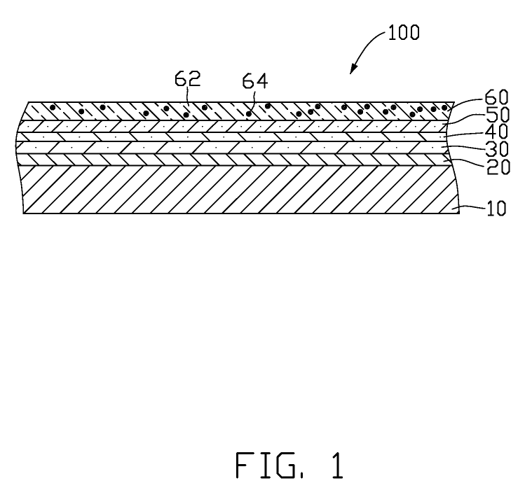

### DETAILED DESCRIPTION OF THE PREFERRED EMBODIMENTS

Embodiments of the present solar cell will now be described in detail below and with reference to the drawing.

Referring to the drawing, an exemplary solar cell 100 according to a first embodiment is shown. The solar cell 100 includes a substrate 10, a back metal-contact layer 20, a P-type semiconductor layer 30, a P-N junction layer 40, an N-type semiconductor layer 50 and a transparent electrically conductive layer 60.

The substrate 10 can be rigid or flexible according to need. A material of the substrate 10 can be selected from glass, ceramic, plastic or stainless steel.

The back metal-contact layer 20 is comprised of a material selected from silver, copper, molybdenum, aluminum, copper aluminum alloy, silver copper alloy, or copper molybdenum alloy. The back metal-contact layer 20 is sputtered onto the substrate 10 by DC magnetron sputtering.

The P-type semiconductor layer 30 is comprised of P-type amorphous silicon doped with hydrogen, or P-type compound. Such P-type compound can be selected from aluminum gallium arsenide (AlGaAs), or aluminum gallium nitride (AlGaN). The P-type semiconductor layer 30 is deposited on the back metal-contact layer 20 by plasma-enhanced chemical vapor deposition (PECVD) or metal-organic chemical vapor deposition (MOCVD).

The P-N junction layer 40 is comprised of copper indium gallium diselenide (Culn₁₋ₓGaSe₂). The P-N junction layer 40 is sputtered onto the P-type semiconductor layer 30 by DC magnetron sputtering.

The N-type semiconductor layer 50 is comprised of N-type amorphous silicon doped with hydrogen, or N-type compound. Such N-type compound can be selected from gallium nitride (GaN), or indium gallium phosphide (InGaP). The N-type semiconductor layer 50 is deposited on the P-N junction layer 40 by plasma-enhanced chemical vapor deposition (PECVD) or metal-organic chemical vapor deposition (MOCVD).

The P-type semiconductor layer 30, the P-N junction layer 40 and the N-type semiconductor layer 50 constitute a semiconductor unit for photon-electron conversion. The P-N junction layer 40 is sandwiched between the P-type semiconductor layer 30 and the N-type semiconductor layer 50, and helps movements of the electrons or holes in the P-type semiconductor layer 30 and the N-type semiconductor layer 50.

The transparent electrically conductive layer 60 is formed on the N-type semiconductor layer 50. The transparent electrically conductive layer 60 functions as a front contact layer. The transparent electrically conductive layer 60 has a basic film 62 and a plurality of photocatalyst nano-particles 64 dispersed in the basic film 62. The basic film 62 can be a transparent electrically conductive oxide film, for example, indium tin oxide (ITO) or zinc oxide, and a thickness of the basic film 62 may be in the range between 300 nm to 900 nm. Alternatively, the basic film 62 can be a carbon nanotube film, and a thickness of the basic film 62 may be in the range between 30 nm to 300 nm. The carbon nanotube film is comprised of a number of carbon nanotubes, and the carbon nanotubes are preferably oriented in parallel with the N-type semiconductor layer 50. Photons in the sunlight are able to pass through the basic film 62. The photocatalyst nano-particles 64 can be titanium dioxide (TiO₂) nano-particles. A size of each of the photocatalyst nano-particles 64 may be in the range between 20 nm to 100 nm. A percentage of the photocatalyst nano-particles 64 in the transparent electrically conductive layer 60 by weight may be in the range from 1% to 5%.

In use, arrange the solar cell 100 on, for example, a roof of a building. Under the sunlight, oxyhydrogen free radicals and oxygen free radicals are produced by the photocatalyst nano-particles 64. Such free radicals are high in activity, and have the ability of decomposing pollutants falling thereon, such as grease or dust. As a result, they keep surfaces of the transparent electrically conductive layer 60 clean. Thus, the entire solar cell 100 has the self cleaning function.

Other particles, such as stannum dioxide (SnO₂) nano-particles, can also be used as the photocatalyst nano-particles.

It is understood that the above-described embodiments are intended to illustrate rather than limit the invention. Variations may be made to the embodiments and methods without departing from the spirit of the invention. Accordingly, it is appropriate that the appended claims be construed broadly and in a manner consistent with the scope of the invention.

What is claimed is:

1. A solar cell, comprising:
a back metal-contact layer;
a P-type semiconductor layer formed on the back metal-contact layer;
a P-N junction layer formed on the P-type semiconductor layer;
an N-type semiconductor layer formed on the P-N junction layer; and
a transparent electrically conductive layer formed on the N-type semiconductor layer for functioning as a front contact layer, the transparent electrically conductive layer having a basic film and a plurality of photocatalyst nano-particles dispersed in the basic film.

2. The solar cell as described in claim 1, wherein the back metal-contact layer is comprised of a material selected from the group consisting of silver, copper, molybdenum, aluminum, copper aluminum alloy, silver copper alloy, and copper molybdenum alloy.

3. The solar cell as described in claim 1, wherein the P-type semiconductor layer is comprised of P-type amorphous silicon doped with hydrogen, or P-type compound.

4. The solar cell as described in claim 1, wherein the N-type semiconductor layer is comprised of N-type amorphous silicon doped with hydrogen, or N-type compound.

5. The solar cell as described in claim 1, wherein the P-N junction layer is comprised of copper indium gallium diselenide.

6. The solar cell as described in claim 1, wherein the basic film of the transparent electrically conductive layer is a transparent electrically conductive oxide film.

7. The solar cell as described in claim 6, wherein a thickness of the basic film is in the range between 300 nm to 900 nm.

8. The solar cell as described in claim 1, wherein the basic film of the transparent electrically conductive layer is a carbon nanotube film.

9. The solar cell as described in claim 8, wherein a thickness of the basic film is in the range between 30 nm to 300 nm.

10. The solar cell as described in claim 1, wherein the photocatalyst nano-particles contain titanium dioxide nano-particles.

11. The solar cell as described in claim 1, wherein a size of each of the photocatalyst nano-particles is in the range between 20 nm to 100 nm.

12. The solar cell as described in claim 1, wherein a percentage of the photo catalyst nano-particles in the transparent electrically conductive layer by weight is in the range from 1% to 5%.
